(19) United States
(12) Patent Application Publication
(10) Pub. No.: US 2006/0202217 A1
(43) Pub. Date: Sep. 14, 2006

(54) Nitride semiconductor light emitting device and method of manufacturing the same

(76) Inventors: Jae Chul Ro, Seoul (KR); Sang Deog Cho, Suwon (KR); Seung Wan Chae, Yongin (KR)

Correspondence Address: LOWE HAUPTMAN BERNER, LLP, 1700 DIAGONAL ROAD, SUITE 300, ALEXANDRIA, VA, 22314, US

(21) Appl. No.: 11/431,001

(22) Filed: May 10, 2006

Related U.S. Application Data
(62) Division of application No. 10/839,284, filed on May 6, 2004.

(30) Foreign Application Priority Data
Jan. 19, 2004 (KR) 2004-3682

(51) Int. Cl. H01L 33/00

(52) U.S. Cl. 257/94

(57) ABSTRACT

A nitride semiconductor light emitting device includes a substrate for growing a gallium nitride-based semiconductor material, an n-type nitride semiconductor layer on the substrate, an active layer on the n-type nitride semiconductor layer such that a predetermined portion of the n-type nitride semiconductor layer is exposed, a p-type nitride semiconductor layer on the active layer, a transparent electrode layer on the p-type nitride semiconductor layer so as to be in an ohmic contact with the p-type nitride semiconductor layer, a p-side bonding pad in the form of a bi-layer of Ta/Au on the transparent electrode layer, and an n-side electrode in the form of a bi-layer of Ta/Au on the exposed portion of the n-type nitride semiconductor layer.

### BACKGROUND OF THE INVENTION

1. Field of the Invention

The present invention relates to a nitride semiconductor light emitting device, and more particularly to a nitride semiconductor light emitting device and a method of manufacturing the same, which comprises a B metal bi-layer and an N metal bi-layer acting as electrodes in the nitride semiconductor light emitting device, thereby providing an ohmic contact at room temperature without additional heat treatment, an improved appearance and superior wire bonding characteristics.

2. Description of the Related Art

Recently, a nitride semiconductor using a nitride, such as gallium nitride (GaN), has been in the spotlight as an essential material for a photoelectric material or an electronic device due to its excellent physical and chemical properties. In particular, a nitride semiconductor light emitting device can generate light having wavelengths of green, blue and UV light, and with a rapid enhancement of brightness by technological development, it also has many applications in several fields, such as a full color video display board, an illuminating apparatus, etc. Such a nitride semiconductor uses a nitride semiconductor material with the formula AlₓIn_{y}Ga_{(1-x-y)}N (where 0≦x≦1, 0≦y≦1, 0≦x+y≦1), and investigations are being actively undertaken particularly on the semiconductor light emitting device using GaN.

In general, the nitride semiconductor light emitting device comprises an n-type nitride semiconductor layer, an active layer with a multi-well structure and a p-type nitride semiconductor layer sequentially laminated in this order on a substrate, in which a predetermined portion of the active layer and p-type nitride semiconductor layer and active layer is removed so that a predetermined portion of the n-type nitride semiconductor layer is exposed. On the exposed n-type nitride semiconductor layer, an n-side electrode (hereinafter, also referred to as “N metal”) is formed, while on the p-type nitride semiconductor layer, a p-side bonding pad (hereinafter, also referred to as “B metal”) is formed on a transparent layer (hereinafter, also referred to as “T metal layer”) previously formed thereon for providing an ohmic contact and enhancing current injection efficiency.

One of the important processes in manufacturing the nitride semiconductor light emitting device is the process for forming electrodes supplying the electric current for a diode. As described above, the electrodes in a general nitride semiconductor light emitting device can comprise the N metal, the T metal layer and the B metal. The N metal should provide the ohmic characteristics in contact with the n-type nitride semiconductor layer, while the T metal layer should exhibit a high transmissivity for light and the ohmic characteristics in contact with the p-type nitride semiconductor layer. Further, since the B metal is used as a bonding pad for wire bonding, the B metal should exhibit excellent bonding characteristics in order to provide a secure wire bonding. The N metal should also exhibit excellent bonding characteristics and ohmic characteristics in contact with the n-type nitride semiconductor layer.

Conventionally, in order to provide low driving voltage and low contact resistance (that is, a low ohmic contact) characteristics for the nitride semiconductor light emitting device, the T metal layer in contact with the p-type nitride semiconductor layer is heat treated after a bi-layer of Ni/Au or an ITO layer is formed, and the B metal for the wire bonding is prepared in the form of a bi-layer of Cr/Au on the T metal layer. Further, the N metal acting as the n-side electrode is prepared in the form of a bi-layer of Ti/Al on the exposed surface of the n-type nitride semiconductor layer.

In such a conventional nitride semiconductor light emitting device, since the B metal and the N metal exhibit deteriorated ohmic characteristics (due to a large contact resistances at room temperature, heat treatment at a temperature of 400° C. or more should be applied for the excellent ohmic characteristics. Further, the process of manufacturing the nitride semiconductor light emitting device becomes complicated, thereby raising costs.

When using Ti/Au as the B metal in the conventional nitride semiconductor light emitting device, due to a serious deterioration in ohmic characteristics, Ti/Au cannot be used as the B metal. As a result, Cr/Au and Ti/Al should be used as the B metal and the N metal, respectively, and these cannot be concurrently formed on the T metal and the n-type nitride semiconductor layer. As such, conventionally, the materials for forming the B metal and N metal should be independently prepared and supplied in different steps, thereby complicating the process and raising costs.

In addition, as one of the materials for forming the N metal according to the conventional method, Al is likely to be dissolved by alkaline solution and to become defective during subsequent machining processes, thereby deteriorating the appearance of the nitride semiconductor light emitting device. Specifically, Al inherently causes defectiveness in the wire bonding due to its inferior bonding characteristics.

Thus, there is a need in the art to provide a new electrode which can be used as the B metal and as the N metal at the same time, and which is excellent in terms of wire bonding characteristics and ohmic characteristics at room temperature.

### SUMMARY OF THE INVENTION

The present invention has been made in view of the above problems, and it is an object of the present invention to provide a nitride semiconductor light emitting device and a method of manufacturing the same, which comprise a B metal bi-layer of Ti/Au and an N metal bi-layer of Ti/Au acting as electrodes in the nitride semiconductor light emitting device, thereby concurrently forming the B metal and N metal, providing an ohmic contact at room temperature without additional heat treatment, improving an inferiority in appearance and providing excellent wire bonding characteristics.

In accordance with an aspect of the present invention, the above and other objects can be accomplished by the provision of a nitride semiconductor light emitting device comprising:

a substrate for growing a gallium nitride-based semiconductor material;

an n-type nitride semiconductor layer formed on the substrate;

an active layer formed on the n-type nitride semiconductor layer such that a predetermined portion of the n-type nitride semiconductor layer is exposed;

a p-type nitride semiconductor layer formed on the active layer;

a transparent electrode layer formed on the p-type nitride semiconductor layer so as to provide an ohmic contact with the p-type nitride semiconductor layer;

a p-side bonding pad in the form of a bi-layer of Ta/Au on the transparent electrode layer; and

an n-side electrode in the form of a bi-layer of Ta/Au on the exposed portion of the n-type nitride semiconductor layer.

The p-side bonding pad may comprise a Ta layer with a thickness of 50 Å˜1,000 Å, and an Au layer with a thickness of 2,000 Å˜7,000 Å formed on the Ta layer. The n-side bonding pad may comprise a Ta layer with a thickness of 50 Å˜1,000 Å, and an Au layer with a thickness of 2,000 Å˜7,000 Å formed on the Ta layer.

In accordance with another aspect of the present invention, there is provided a method of manufacturing a nitride semiconductor light emitting device, the method comprising the steps of:

a) preparing a substrate for growing a nitride semiconductor material;

b) forming an n-type nitride semiconductor layer, an active layer, and a p-type nitride semiconductor layer, sequentially, on the substrate;

c) removing a predetermined portion of the p-type nitride semiconductor layer and active layer to expose a predetermined portion of the n-type nitride semiconductor layer;

d) forming a transparent electrode layer on the p-type nitride semiconductor layer;

e) forming a p-side bonding pad in the form of a bi-layer of Ta/Au on the transparent electrode layer; and

f) forming an n-side electrode in the form of a bi-layer of Ta/Au on the exposed portion of the n-type nitride semiconductor layer.

In the method of the present invention, the steps e) and f) may be executed at the same time.

The step e) may comprise the step of sequentially depositing Ta and Au on the p-type nitride semiconductor with an electron beam evaporating process. Similarly, the step f) may comprise the step of sequentially depositing Ta and Au on the n-type nitride semiconductor with an electron beam evaporating process.

The method of the present invention may further comprise the step of heat treating the p-side bonding pad and the n-side bonding pad at a temperature of 400° C.˜600° C.

### BRIEF DESCRIPTION OF THE DRAWINGS

The above and other objects and features of the present invention will be more clearly understood from the following detailed description taken in conjunction with the accompanying drawings, in which:

FIG. 1 is a sectional view of a nitride semiconductor light emitting device according to the present invention;

FIGS. 2a to 2d are photographs comparing the appearance of a conventional n-side electrode and that of an n-side electrode according to the present invention;

FIGS. 3a and 3b are graphs showing ohmic characteristics of the conventional n-side electrode comprising Ti/Al and those of the n-side electrode comprising Ti/Au according to the present invention; and

FIG. 4 is a graph showing the result of the test examining the reliability of the conventional nitride semiconductor light emitting device and that of the nitride semiconductor light emitting device according to the present invention.

### DESCRIPTION OF THE PREFERRED EMBODIMENTS

A nitride semiconductor light emitting device and a method of manufacturing the same according to an embodiment of the present invention will now be described in detail with reference to the accompanying drawings.

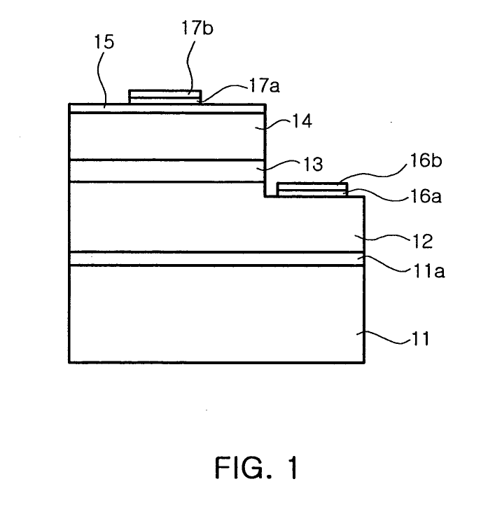

FIG. 1 is a sectional view of a nitride semiconductor light emitting device according to the embodiment of the present invention. Referring to FIG. 1, the nitride semiconductor light emitting device comprises a substrate 11, preferably a sapphire substrate, for growing a gallium nitride-based semiconductor material, a buffer layer 11a formed on the substrate 11 for alleviating the lattice mismatching between a sapphire substrate and an n-type nitride semiconductor layer to be grown on the substrate, the n-type nitride semiconductor 12 layer formed on the buffer layer, an active layer 13 formed on the n-type nitride semiconductor layer such that a predetermined portion of the n-type nitride semiconductor layer 12 is exposed, a p-type nitride semiconductor layer 14 formed on the active layer, a transparent electrode layer 15 formed on the p-type nitride semiconductor layer, a p-side bonding pad 17 in the form of a bi-layer of Ta/Au on the transparent electrode layer 15, and an n-side electrode 16 in the form of a bi-layer of Ta/Au on the exposed portion of the n-type nitride semiconductor layer.

Although either a sapphire substrate or a SiC substrate can be used for the substrate 11, the sapphire substrate is more representative. With regard to this, it is impossible to provide a commercially available substrate which has an identical crystal structure to that of a nitride semiconductor material grown on the substrate 11, and which is in lattice matching with the nitride semiconductor material. Meanwhile, the sapphire substrate has a crystal structure of a hexa-rhombic (R3) symmetry with lattice parameters of 13.001 Å in the direction of the c-axis and a lattice spacing of 4.765 Å in the direction of the a-axis. The indices of the sapphire plane contain C(0001) plane, A(1120) plane, R(1102) plane, etc. As for light emitting devices emitting light having wavelengths of blue and green, the sapphire substrate is preferred to the SiC substrate, due to the relative easy of growing a GaN thin film on the C plane therein, lower price, and stability at a high temperature.

The buffer layer 11a is formed to alleviate the lattice mismatching between the substrate 11 and the n-type nitride semiconductor layer grown on the substrate 11. As for the buffer layer, GaN layer or AlN layer with a thickness several dozen nm is typically used.

The n-type nitride semiconductor layer 12 comprises a semiconductor material doped with n-type impurities, having the formula AlₓIn_{y}Ga_{(1-x-y)}N (where 0≦x≦1, 0≦y≦1, 0≦x+y≦1). Specifically, GaN is usually employed. The n-type nitride semiconductor layer 12 is grown on the substrate with a well-known deposition process, such as the MOCVD (Metal Organic Chemical vapor Deposition) process or the MBE (Molecular Beam Epitaxy) process.

The active layer 13 has a quantum-well structure and may comprise GaN or InGaN.

Like the n-type nitride semiconductor layer 12, the p-type nitride semiconductor layer 14 comprises an n-type semiconductor material doped with p-type impurities and with the formula AlₓIn_{y}Ga_{(1-x-y)}N (where 0≦x≦1, 0≦y≦1, 0≦x+y≦1). The p-type nitride semiconductor layer 14 is also grown on the active layer 13 with a well-known deposition process, such as the MOCVD process or the MBE process.

Since the p-type nitride semiconductor layer 14 has a high contact resistance due to a low concentration of impurity being doped, ohmic characteristics are inferior. In order to improve the ohmic characteristics, the transparent electrode layer 15 (which is also referred to as a T metal) is formed on the p-type nitride semiconductor layer 14. The transparent electrode layer 15 may comprise a metal with a relatively high transmissivity, and a transparent electrode layer comprising a bi-layer of Ni/Au is widely used. It is known that the transparent electrode layer comprising the bi-layer of Ni/Au lowers a forward voltage (V_{f}) by providing an ohmic contact along with an increase of current injection areas.

The n-side electrode 16 (which is also referred to as an N metal) is formed in the form of a bi-layer of Ta/Au on the exposed portion of the n-type nitride semiconductor layer 12. The n-side electrode 16 should have good wire bonding characteristics so as to form a wire bonding for supplying the electric current, and have the ohmic contact with the n-type nitride semiconductor layer. Through repeated investigations and studies on the most suitable material fulfilling the characteristics of such an n-side electrode 16, the inventors found that the n-side electrode in the form of a bi-layer of Ta/Au is the most preferable. The n-side electrode 16 comprising Ta/Au is prepared by forming an Ta layer 16a with a thickness of 50 Å˜1,000 Å on the p-type semiconductor layer and forming an Au layer 16b with a thickness of 2,000 Å˜7,000 Å on the Ta layer 16a, with the well-known electron beam evaporating process.

The n-side electrode 16 comprising Ta/Au has characteristics of providing the ohmic contact even at room temperature. As the conventional n-side electrode 16 using Ti/Al does not provide the ohmic contact at room temperature, the ohmic characteristics thereof should be improved through heat treatment at high temperature. On the other hand, according to the present invention, as the n-side electrode comprising Ta/Au can provide the ohmic contact at room temperature, additional heat treatment is not required. Thus, the process of manufacturing the nitride semiconductor light emitting device can be simplified, thereby reducing costs. Further, since Al, which is likely to be corroded in alkali solution and defected in subsequent processes is not used, the present invention has an advantage that the appearance of the nitride semiconductor light emitting device is not defected.

The p-side bonding pad 17 is prepared to form the wire bonding for the electric current, and prepared on the transparent electrode layer 15 in the form of the bi-layer comprising the Ta layer and the Au layer, like the n-side bonding pad 16. The p-side bonding pad 17 (which is also referred to as B metal) comprising Ta/Au may be prepared by forming a Ta layer 17a with a thickness of 50 Å˜1,000 Å on the p-side nitride semiconductor and forming an Au layer 17b with a thickness of 2,000 Å˜7,000 Å on the Ta layer 17a, using the well-known E-beam evaporating process. Since the p-side bonding pad 17 comprising Ta/Au consists of materials that are identical to those of the n-side electrode 16, it can be formed concurrently with the n-side electrode. Thus, the present invention has an advantage of providing a more simplified process than the conventional process, separately forming the n-side electrode and the p-side bonding electrode.

The n-side electrode 16 and the p-side bonding electrode 17 have good ohmic characteristics without heat treatment. In addition, they also have good ohmic characteristics with heat treatment at 400° C.˜600° C. Thus, the n-side electrode 16 and the p-side bonding electrode 17 in the nitride semiconductor light emitting device of the present invention are allowed to have heat treatment at a temperature of 400° C.˜600° C. Further, it is known that the bonding characteristics of Au are superior to those of Al. Thus, the n-side electrode and the p-side bonding electrode according to the present invention have superior bonding characteristics to the conventional electrode.

The present invention also provides a method of manufacturing the nitride semiconductor with the construction as described above. The method of manufacturing the nitride semiconductor according to an embodiment of the present invention will now be described with reference to FIG. 1.

First, after the sapphire substrate 11 for growing the nitride semiconductor material is prepared, the n-type nitride semiconductor layer 12, the active layer 13, and the p-type nitride semiconductor layer 14 are sequentially formed on the sapphire substrate 11. These layers can be grown with a well-known process, such as the MOCVD process or the MBE process.

Subsequently, a predetermined portion of the p-type nitride semiconductor layer 14 and active layer 13 is removed so as to expose a predetermined portion of the n-type nitride semiconductor layer 14. The shape of the constructions formed by the removing step can be variously prepared depending on the places where the electrodes are to be formed. Various shapes and sizes of electrodes can also be provided. For example, this step can be executed in a manner that a portion in contact-with one of the edges can be removed and the shape of electrodes can be formed to have structure extending along a side for dissipating the current density.

Then, the transparent electrode layer 15 is sequentially formed on the p-type nitride semiconductor layer 14. As described above, the transparent electrode layer 15 is generally prepared in the form of the bi-layer of Ni/Au and can be deposited using the well-known electron beam evaporating process.

Finally, the p-side bonding pad 17 in the form of the bi-layer of Ta/Au and the n-side electrode 16 in the form of the bi-layer of Ta/Au are concurrently formed on the transparent electrode layer 15 and on the exposed portion of the n-type nitride semiconductor layer 12, respectively. Since the p-side bonding pad 17 and the n-side electrode 16 consist of the same materials, there are provided the characteristics that these can be concurrently formed with one process. By this, the process of the invention can be more simplified than the conventional process separately forming the n-side electrode and the p-side bonding electrode. The p-side bonding pad 17 and the n-side electrode 16 may be formed by sequentially depositing Ta and Au with the well-known electron beam evaporating process. Preferably, the Ta layer consisting of the n-side electrode 16 and the p-side bonding electrode 17 has a thickness of 50 Å˜1,000 Å, and the Au layer has a thickness of 2,000 Å˜7,000 Å on the Ta layer.

The n-side electrode 16 and the p-side bonding electrode 17 according to the invention provide good ohmic characteristics without heat treatment. In addition, they also may provide good ohmic characteristics even after the heat treatment at 400° C.˜600° C. Thus, according to the method of the present invention, it does not matter if the n-side electrode 16 and the p-side bonding electrode 17 of the present invention are heat treated at a temperature of 400° C.˜600° C.

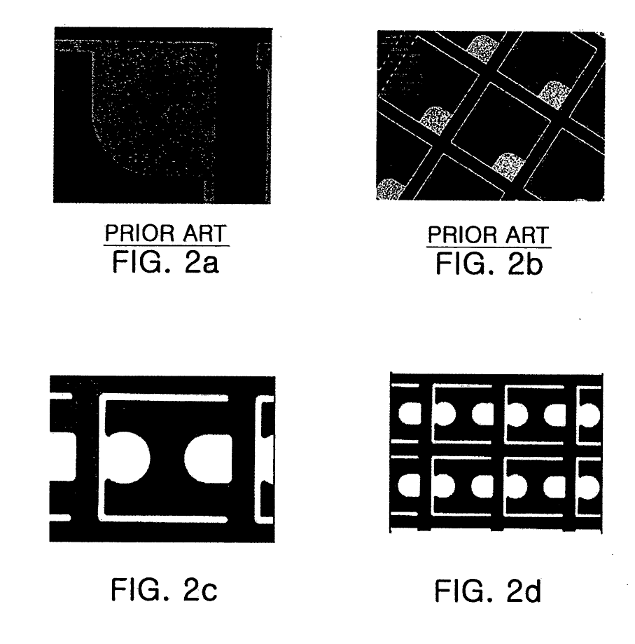

FIGS. 2a to 2d are photographs comparing the appearance of the conventional n-side electrode and that of the n-side electrode according to the present invention. As shown in FIG. 2a, the conventional n-side electrode has defects in the appearance with stains due to damage to the Al. Further, as shown in FIG. 2b, there arises a spot inferiority by spots on the conventional n-side electrode. On the contrary, as shown in FIGS. 2c and 2d, the n-side electrode of the nitride semiconductor light emitting device of the present invention does not have a spoiled appearance. According to the present invention, as shown in FIG. 2, the problem of the defectiveness of the appearance due to the damage on the n-side electrode can be overcome.

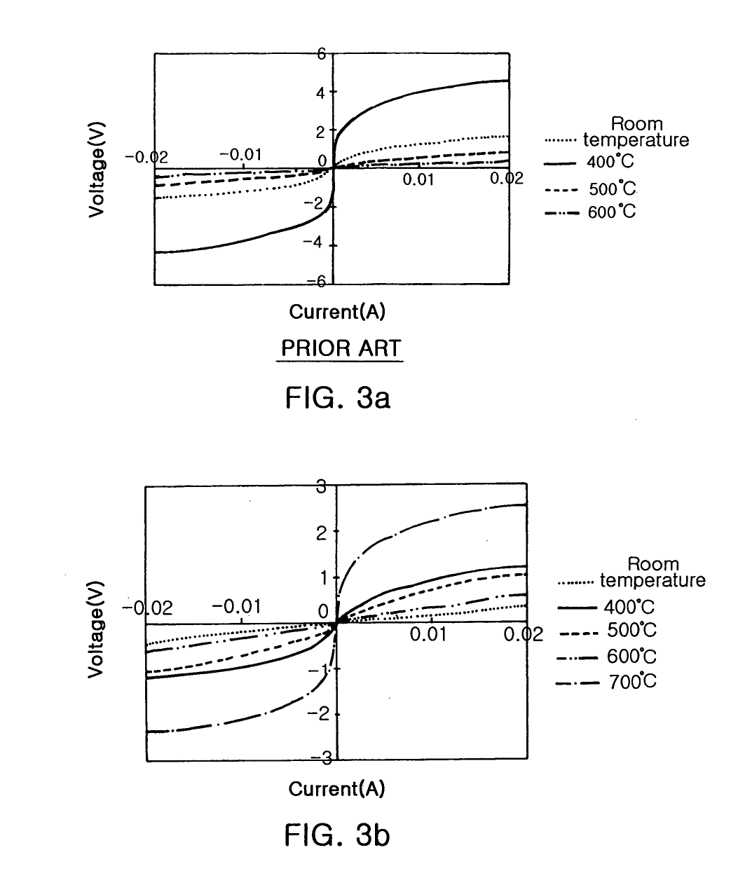

FIGS. 3a and 3b are a graph showing ohmic characteristics of the conventional n-side electrode comprising Ti/Al and those of the n-side electrode comprising Ta/Au of the present invention. As shown in FIG. 3a, the conventional n-side electrode comprising Ti/Al does not provide the ohmic contact at room temperature. Instead, when the conventional n-side electrode comprising Ti/Al is heat treated at 500° C.˜600° C., it generates the ohmic contact at room temperature. Thus, the conventional Ti/Al electrode provides the ohmic contact when being subjected to heat treatment at a high temperature of 500° C. or more.

On the contrary, as shown in FIG. 3b, the n-side electrode comprising Ta/Au of the present invention exhibits relatively good ohmic characteristics even at room temperature. In addition, since the n-side electrode of the present invention exhibits a good ohmic contact at 400° C.˜600° C., not at 700° C., it does not matter that the Ta/Au electrode of the present invention is heat treated at 400° C.˜600° C.

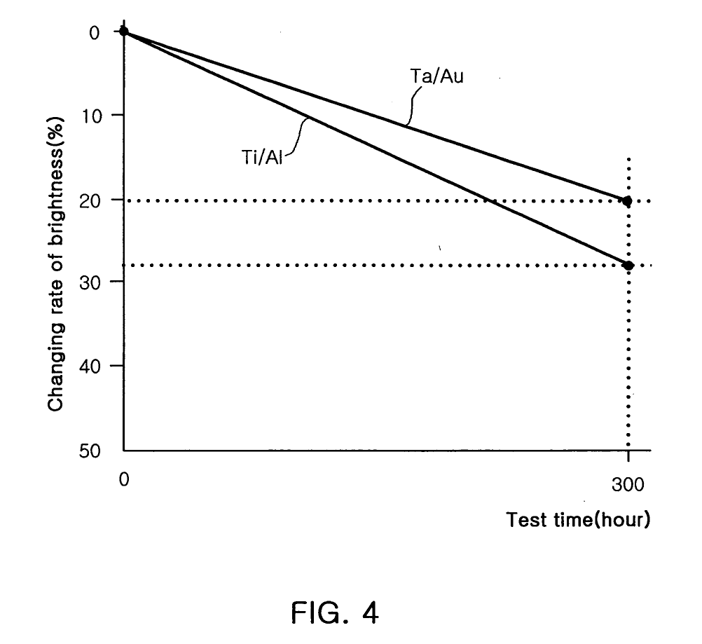

FIG. 4 shows the result of the test examining the reliability of the conventional nitride semiconductor light emitting device having the conventional n-side electrode comprising Ti/Al and that of the nitride semiconductor light emitting device having the n-side electrode comprising Ta/Al of the present invention. As shown in FIG. 4, the nitride semiconductor light emitting device having the conventional n-side electrode comprising Ti/Al exhibits a reduction in brightness-of about 25% after 300 hours of use, while the nitride semiconductor light emitting device having the n-side electrode comprising Ta/Al of the present invention exhibits a reduction in brightness of about 20% after 300 hours of use. Thus, the reliability of the light emitting device according to the present invention is considerably improved.

As described above, the present invention can simplify the manufacturing process by providing the p-side electrode and the n-side electrode comprising the bi-layer of Ti/Au, respectively, and reduce the defects in the appearance and the wire bonding characteristics by not using Al constituting the conventional electrode. In addition, the present invention provides an excellent nitride semiconductor light emitting device with a superior reliability to the conventional light emitting device.

As is apparent from the above description, according to the present invention, since the B metal and the N metal acting as the electrodes in the light emitting device can be concurrently formed and provide the ohmic contact without additional heat treatment by forming them in the form of the bi-layers of Ta/Au, an advantageous effect of reducing costs can be achieved with a simplified manufacturing process. Further provided is an advantageous effect of forming the nitride semiconductor light emitting device with an improved appearance and superiority in the wire bonding characteristics by not using Al for its materials.

Although the preferred embodiment of the present invention have been disclosed for illustrative purpose, those skilled in the art will appreciate that various modifications, additions and substitutions are possible without departing from the scope and spirit of the invention as disclosed in the accompanying claims.

1-3. (canceled)

4. A method of manufacturing a nitride semiconductor light emitting device, the method comprising the steps of:
a) preparing a substrate for growing a nitride semiconductor material;
b) forming an n-type nitride semiconductor layer, an active layer, and a p-type nitride semiconductor layer, sequentially, on the substrate;
c) removing a predetermined portion of the p-type nitride semiconductor layer and active layer to expose a predetermined portion of the n-type nitride semiconductor layer;
d) forming a transparent electrode layer on the p-type nitride semiconductor layer;
e) forming a p-side bonding pad in the form of a bi-layer of Ta/Au on the transparent electrode layer; and
f) forming an n-side electrode in the form of a bi-layer of Ta/Au on the exposed portion of the n-type nitride semiconductor layer.

5. The method as set forth in claim 4, wherein the step e) and the step f) are executed at the same time.

6. The method as set forth in claim 4, wherein the step e) comprises the step of sequentially depositing Ta and Au on the p-type nitride semiconductor with an electron beam evaporating process.

7. The method as set forth in claim 4, wherein the step f) comprises the step of sequentially depositing Ta and Au on the n-type nitride semiconductor with an electron beam evaporating process.

8. The method as set forth in claim 4, wherein the step e) comprises the steps of:
forming a Ta layer with a thickness of 50 Å˜1,000 Å on the p-side nitride semiconductor layer; and
forming an Au layer with a thickness of 2,000 Å˜7,000 Å formed on the Ta layer.

9. The method as set forth in claim 4, wherein the step f) comprises the step of:
forming a Ta layer with a thickness of 50 Å˜1,000 Å on the n-side nitride semiconductor layer; and
forming an Au layer with a thickness of 2,000 Å˜7,000 Å formed on the Ta layer.

10. The method as set forth in claim 4, the method further comprising the step of:
g) heat treating the p-side bonding pad and the n-side bonding pad at a temperature of 400° C.˜600° C.
